(19) United States
(12) Patent Application Publication
(10) Pub. No.: US 2021/0091120 A1
(43) Pub. Date: Mar. 25, 2021

(54) TFT ARRAY SUBSTRATE AND MANUFACTURING METHOD THEREOF

(71) Applicant: Shenzhen China Star Optoelectronics Semiconductor Display Technology Co., Ltd., Shenzhen (CN)

(72) Inventors: Huafei Xie, Shenzhen (CN); Shujhih Chen, Shenzhen (CN)

(73) Assignee: Shenzhen China Star Optoelectronics Semiconductor Display Technology Co., Ltd., Shenzhen (CN)

(21) Appl. No.: 16/308,480

(22) PCT Filed: Sep. 20, 2018
(86) PCT No.: PCT/CN2018/106605

§ 371 Date: Dec. 10, 2018

(30) Foreign Application Priority Data
Jul. 9, 2018 (CN) 201810747018.6

(51) Int. Cl. H01L 27/12

(52) U.S. Cl. CPC H01L 27/1225; H01L 27/127

(57) ABSTRACT

The invention provides a TFT array substrate and manufacturing method thereof. The manufacturing method adopts a dual-layer structure for the active layer. The first active layer adopts a new semiconductor material of carbon nanotubes, graphene, silicon carbide, molybdenum disulfide or organic semiconductor materials. The second active layer is disposed on the first active layer to protect the first active layer of the new semiconductor material from the wet etching and CVD process as an etch stop layer and facilitates the active layer of the TFT device to possess combined excellent properties of two semiconductor materials.

### BACKGROUND OF THE INVENTION

### 1. Field of the Invention

The present invention relates to the field of display, and in particular to a thin film transistor (TFT) array substrate and manufacturing method thereof.

### 2. The Related Arts

The liquid crystal display (LCD) provides many advantages, such as, thinness, power saving, no radiation, an so on, and has been widely used, such as, mobile phones, personal digital assistants (PDAs), digital cameras, computer screens or notebooks, computer screens, and so on.

The organic light-emitting diode (OLED) display, also known as an organic electroluminescent display, is an emerging panel display device. Because of the advantages of simple manufacturing process, low cost, low power consumption, and high luminance, wide range of operation temperature, light-weight and thinness, fast response speed, easy to realize color display and large screen display, easy to realize matching with integrated circuit driver, easy to realize flexible display, and so on, the OLED is heralded for broad range of applications.

According to the driving method, the OLED display device can be divided into two types: passive matrix OLED (PMOLED) and active matrix OLED (AMOLED), namely, direct addressing and thin film transistor (TFT) matrix addressing categories, wherein the AMOLED has the pixels arranged in an array, belongs to an active display type, has high light emission efficiency, and is generally used for a high-definition large-sized display device.

The TFT is the main driver in the known LCD and AMOLED, and is directly related to the development direction of high-performance panel display devices.

The TFT can be of various structures, and the material of the TFT active layer for preparing the corresponding structure is also various. For example, new semiconductor materials, such as, graphene, carbon nanotube, silicon carbide, molybdenum disulfide and the like, because of high mobility and suitability for use in the preparation of flexible transparent devices, have gained great attention in the field of TFT. However, these new semiconductor materials have a common feature. When manufacturing a transistor, these new materials can only be patterned by dry etching, while the acid wet etching and chemical vapor deposition (CVD) process can easily cause damage and chemical doping to the semiconductor materials.

Therefore, it is imperative to devise a manufacturing process for protecting the transistor made of new semiconductor materials.

### SUMMARY OF THE INVENTION

The object of the present invention is to provide a manufacturing method for TFT array substrate, by disposing an active layer of dual-layer structure, able to protect the first active layer made of new semiconductor material from damages caused by wet etching and CVD, as well as facilitating the active layer of the TFT device to possess combined excellent properties of two semiconductor materials and lowering the production cost.

Another object of the present invention is to provide a TFT array substrate, with an active layer having higher mobility and less defects in thin film to improve reliability of the TFT device.

To achieve the above object, the present invention provides a manufacturing method of TFT array substrate, which comprises:

Step S1: providing a substrate, depositing a first metal film on the substrate, patterning the first metal film to form a gate, and forming a gate insulating layer covering the gate on the substrate;

Step S2: forming a first semiconductor film on the gate insulating layer, material of the first semiconductor film being an inorganic semiconductor material or an organic semiconductor material;

Step S3: forming a second semiconductor film on the first semiconductor film and patterning the second semiconductor film to obtain a second active layer corresponding to above of the gate; material of the second semiconductor film is metal oxide semiconductor material;

Step S4: depositing a second metal film on the first semiconductor film and the second active layer and patterning to form a drain and a source, the drain and the source respectively extending from both ends of the second active layer onto the first semiconductor film;

Step S5: using the drain, the source, and the second active layer as a shielding layer, performing etching processing on the first semiconductor film to obtain a first active layer, where the first active layer and the second active layer collectively forming an active layer.

In a preferred embodiment, the manufacturing method of the TFT array substrate further comprises:

Step S6: forming a passivation layer covering the drain, the source, and the active layer on the gate insulating layer; forming a via corresponding to above of the drain on the passivation layer;

Step S7: depositing a third metal film on the passivation layer and patterning to form a pixel electrode, wherein the pixel electrode being connected to the drain through the via.

In a preferred embodiment, the material of the first semiconductor film is carbon nanotubes, graphene, silicon carbide, molybdenum disulfide or an organic semiconductor material;

the material of the second active layer is indium gallium zinc oxide (IGZO), indium oxide, zinc oxide, copper indium sulfide or indium gallium arsenide.

In a preferred embodiment, in step S5, the first semiconductor film is etched by plasma dry etching.

In a preferred embodiment, in step S3, the second semiconductor film is formed by magnetron sputtering or chemical vapor deposition (CVD);

in step S3, the specific process of patterning the second semiconductor film comprises a photoresist coating step, an exposure step, a development step, an etching step, and a photoresist removal step, all sequentially performed; wherein, the etching step on the second semiconductor film being performed by wet etching.

In a preferred embodiment, in step S2, the first semiconductor film is formed by coating.

In a preferred embodiment, the substrate provided in step S1 is a polyimide substrate, a polyethylene terephthalate substrate or a glass substrate;

the material of the gate formed in step S1 is indium tin oxide (ITO) or one or more metal materials of molybdenum, aluminum, copper, titanium, and cadmium;

the gate insulating layer formed in step S1 is a silicon nitride layer, a silicon oxide layer, a hafnium oxide layer, an aluminum oxide layer or an organic insulating layer;

the material of the drain and the source formed in step S4 is ITO or one or more metal materials of molybdenum, aluminum, copper, titanium, and cadmium;

the passivation layer formed in step S6 is a silicon nitride layer, a silicon oxide layer, a hafnium oxide layer, an aluminum oxide layer or an organic insulating layer.

The present invention also provides a TFT array substrate, comprising: a substrate, a gate disposed on the substrate, a gate insulating layer disposed on the substrate and covering the gate, and an active layer disposed on the gate insulating layer and corresponding to above of the gate, and a drain and a source disposed on the active layer and respectively contacting two ends of the active layer;

the active layer comprising a first active layer disposed on the gate insulating layer, and a second active layer disposed on the first active layer covering a middle portion of the first active layer, the drain and the source extending from both ends of the second active layer onto the first active layer, respectively;

material of the first active layer being an inorganic semiconductor material or an organic semiconductor material;

material of the second active layer being a metal oxide semiconductor material.

In a preferred embodiment, the material of the first active layer is carbon nanotubes, graphene, silicon carbide, molybdenum disulfide or an organic semiconductor material;

the material of the second active layer is indium gallium zinc oxide (IGZO), indium oxide, zinc oxide, copper indium sulfide or indium gallium arsenide.

In a preferred embodiment, the TFT array substrate further comprises: a passivation layer disposed on the gate insulating layer and covering the drain and the source, a via disposed on the passivation layer and corresponding to above of the drain, and a pixel electrode disposed on the passivation layer; the pixel electrode being connected to the drain through the via;

the substrate is a polyimide substrate, a polyethylene terephthalate substrate or a glass substrate;

the material of the gate is indium tin oxide (ITO) or one or more metal materials of molybdenum, aluminum, copper, titanium, and cadmium;

the gate insulating layer is a silicon nitride layer, a silicon oxide layer, a hafnium oxide layer, an aluminum oxide layer or an organic insulating layer;

the material of the drain and the source is ITO or one or more metal materials of molybdenum, aluminum, copper, titanium, and cadmium;

the passivation layer is a silicon nitride layer, a silicon oxide layer, a hafnium oxide layer, an aluminum oxide layer or an organic insulating layer.

The present invention provides the following advantages: the invention provides a manufacturing method of TFT array substrate, wherein the active layer is provided as a dual-layer structure. The first active layer adopts a new semiconductor material of carbon nanotubes, graphene, silicon carbide, molybdenum disulfide or organic semiconductor materials. The second active layer is disposed on the first active layer to protect the first active layer of the new semiconductor material from the wet etching and CVD process as an etch stop layer and facilitates the active layer of the TFT device to possess combined excellent properties of two semiconductor materials and lowering the production cost. Therefore, the TFT array substrate manufactured by the method of the present invention has an active layer having higher mobility and less defects in thin film to improve reliability of the TFT device.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the flowchart of the manufacturing method of TFT array substrate of the present invention;

FIG. 2 is a schematic view showing step S1 of the manufacturing method of TFT array substrate of the present invention;

FIG. 3 is a schematic view showing step S2 of the manufacturing method of TFT array substrate of the present invention;

FIGS. 4-5 are schematic views showing step S3 of the manufacturing method of TFT array substrate of the present invention;

FIGS. 6-7 are schematic views showing step S4 of the manufacturing method of TFT array substrate of the present invention;

FIG. 8 is a schematic view showing step S5 of the manufacturing method of TFT array substrate of the present invention;

FIG. 9 is a schematic view showing step S6 of the manufacturing method of TFT array substrate of the present invention;

FIG. 10 is a schematic view showing step S7 of the manufacturing method of TFT array substrate and the structure of the TFT array substrate of the present invention.

### DETAILED DESCRIPTION OF THE PREFERRED EMBODIMENTS

To further explain the technical means and effect of the present invention, the following refers to embodiments and drawings for detailed description.

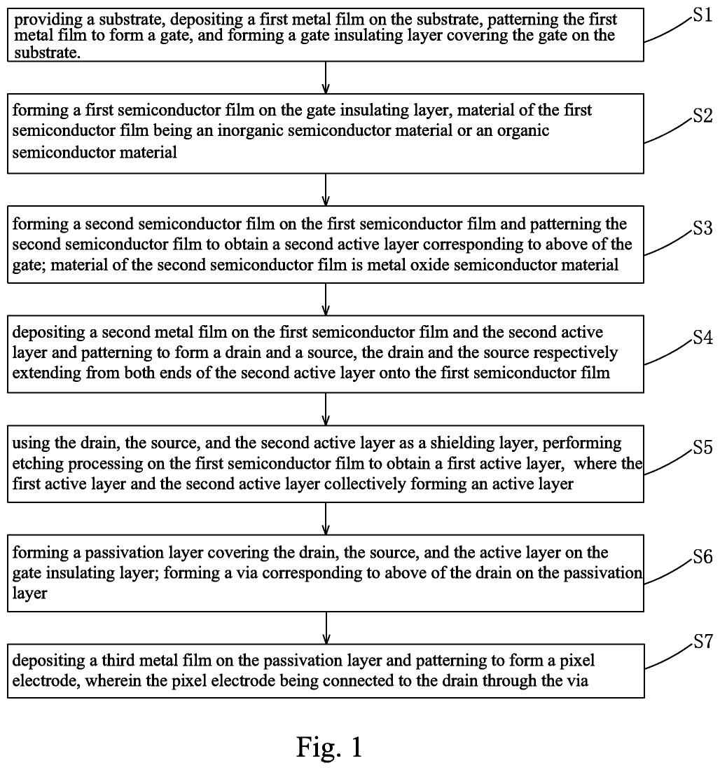

Refer to FIG. 1. The present invention provides a manufacturing method of TFT array substrate, which comprises the following steps of:

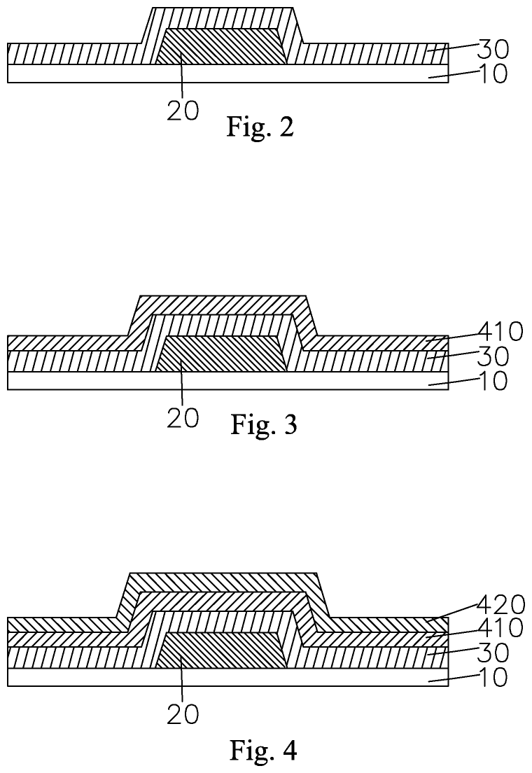

Step S1: as shown in FIG. 2, providing a substrate 10, cleaning the substrate 10, depositing a first metal film on the substrate 10 by physical vapor deposition (PCD) entirely, patterning the first metal film to form a gate 20, and after cleaning the substrate 10, forming a gate insulating layer 30 covering the gate 20 on the substrate 10 by CVD.

Specifically, the substrate 10 provided in step S1 is a polyimide (PI) substrate, a polyethylene terephthalate (PET) substrate or a glass substrate, wherein the glass substrate can be quartz glass, silicon oxide glass, and so on.

Specifically, the material of the gate 20 formed in step S1 is indium tin oxide (ITO) or one or more metal materials of molybdenum (Mo), aluminum (Al), copper (Cu), titanium (Ti), and cadmium (Cr); moreover, in the present embodiment, the gate 20 is made of a Mo/Al alloy.

Specifically, the gate insulating layer 30 formed in step S1 is a silicon nitride (Si₃N₄) layer, a silicon oxide (SiO₂) layer, a hafnium oxide (HfO₂) layer, an aluminum oxide (Al₂O₃) layer or an organic insulating layer; moreover, in the present embodiment, an entire Si₃N₄ layer is formed by CVD using decane (SiH₄) and ammonia (NH₃) as reactive gases to form the gate insulating layer 30.

Step S2: as shown in FIG. 3, cleaning the substrate 10 after step S1, forming a first semiconductor film 410 on the gate insulating layer 30.

Specifically, in step S2, the first semiconductor film 410 is formed using another new semiconductor material, such as, carbon nanotubes (SWCNT), graphene, silicon carbide (SiC), molybdenum disulfide (MoS₂), or an organic semiconductor material.

Moreover, in the present embodiment, a film is formed by coating a carbon nanotube solution on the gate insulating layer 30, and dried to obtain the first semiconductor film 410.

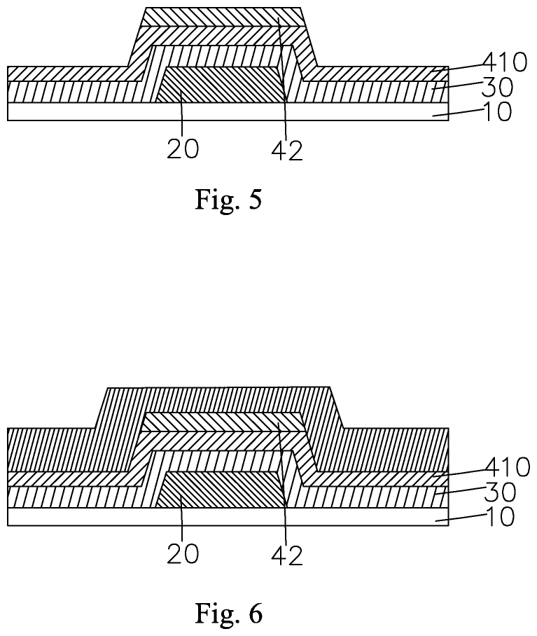

Step S3: as shown in FIGS. 4-5, cleaning the substrate 10 after step S2, using magnetron sputtering or CVD to form a second semiconductor film 420 on the first semiconductor film 410 and patterning the second semiconductor film 420 to obtain a second active layer 42 corresponding to above of the gate 20.

Specifically, the material of the second active layer 42 formed in step S3 is indium gallium zinc oxide (IGZO), indium oxide (In₂O₃), zinc oxide (ZnO), copper indium sulfide (CuInS₂) or indium gallium arsenide (GaₓIn₁₋ₓAs), or other metal oxide semiconductor materials.

Specifically, in step S3, the specific process of patterning the second semiconductor film 420 comprises a photoresist coating step, an exposure step, a development step, an etching step, and a photoresist removal step, all sequentially performed; wherein, the etching step on the second semiconductor film 420 is performed by wet etching.

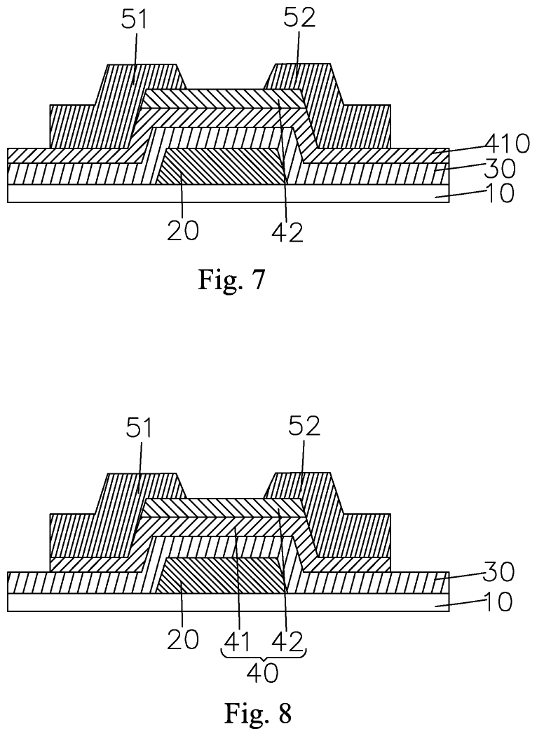

Step S4: as shown in FIG. 6-7, cleaning the substrate 10 after step S3, using

magnetron sputtering or CVD to deposit a second metal film on the first semiconductor film 410 and the second active layer 42 entirely and patterning to form a drain 51 and a source 52, the drain 51 and the source 52 respectively extending from both ends of the second active layer 42 onto the first semiconductor film 410.

Specifically, in step S4, the specific process of patterning the second metal film comprises a photoresist coating step, an exposure step, a development step, an etching step, and a photoresist removal step, all sequentially performed; wherein the etching step on the second metal film is performed by wet etching.

Specifically, the material of the drain 51 and the source 52 formed in step S4 is indium tin oxide (ITO) or one or more metal materials of molybdenum (Mo), aluminum (Al), copper (Cu), titanium (Ti), and cadmium (Cr).

Step S5: as shown in FIG. 8, using the drain 51, the source 52, and the second active layer 42 as a shielding layer, performing etching processing on the first semiconductor film 410 to obtain a first active layer 41, where the first active layer 41 and the second active layer 42 collectively forming an active layer 40.

Specifically, in step S5, the first semiconductor film 410 is etched by plasma dry etching.

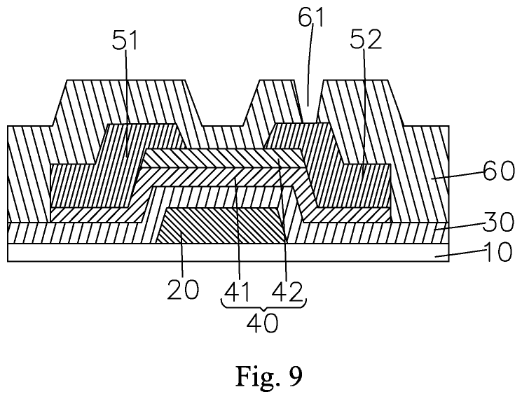

Step S6: as shown in FIG. 9, forming a passivation layer 60 covering the drain 51, the source 52, and the active layer 40 on the gate insulating layer 30; patterning the passivation layer 60 to form a via 61 corresponding to above of the drain 51 on the passivation layer 60.

Specifically, the passivation layer 60 formed in step S6 is a silicon nitride layer, a silicon oxide layer, a hafnium oxide layer, an aluminum oxide layer or an organic insulating layer.

Moreover, in the present embodiment, step S6 prepares the entire silicon oxide layer by CVD using nitrous oxide (N₂O) and decane (SiH₄) as a reaction gas to obtain the passivation layer 60.

Specifically, in step S6, the specific process of patterning the passivation layer 60 comprises a photoresist coating step, an exposure step, a development step, an etching step, and a photoresist removal step, all sequentially performed; wherein the etching step on the passivation layer 60 is performed by plasma dry etching.

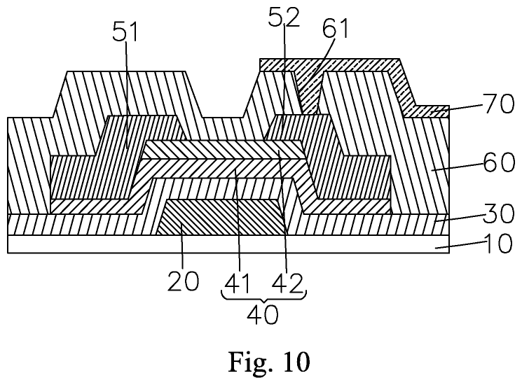

Step S7: as shown in FIG. 10, depositing a third metal film on the passivation layer 60 and patterning to form a pixel electrode 70, wherein the pixel electrode 70 is connected to the drain 51 through the via 61.

The manufacturing method of TFT array substrate of the present invention adopts a dual-layer structure for the active layer. The first active layer 41 adopts a new semiconductor material of carbon nanotubes, graphene, silicon carbide, molybdenum disulfide or organic semiconductor materials. The second active layer 42 is disposed on the first active layer 41 to protect the first active layer 41 of the new semiconductor material from the wet etching and CVD process as an etching stop layer (ESL) and facilitates the active layer 40 of the TFT device to possess combined excellent properties of two semiconductor materials and lowering the production cost. Therefore, the TFT array substrate manufactured by the method of the present invention has an active layer 40 having higher mobility and less defects in thin film to improve reliability of the TFT device.

Refer to FIG. 10. Based on the above manufacturing method of TFT array substrate, the present invention also provides a TFT array substrate, comprising: a substrate 10, a gate 20 disposed on the substrate 10, a gate insulating layer 30 disposed on the substrate 10 and covering the gate 20, and an active layer 40 disposed on the gate insulating layer 30 and corresponding to above of the gate 20, a drain 51 and a source 52 disposed on the active layer 40 and respectively contacting two ends of the active layer 40, a passivation layer 50 disposed on the gate insulating layer 30 and covering the drain 41, the source 52 and the active layer 40, a via 60 disposed on the passivation layer 60 and corresponding to above of the drain 51, and a pixel electrode 70 disposed on the passivation layer 60;

the pixel electrode 70 being connected to the drain 51 through the via 61;

the active layer 40 comprising a first active layer 41 disposed on the gate insulating layer 30, and a second active layer 42 disposed on the first active layer 41 covering a middle portion of the first active layer 41, the drain 51 and the source 52 extending from both ends of the second active layer 40 onto the first active layer 41, respectively; the material of the first active layer 41 being carbon nanotubes, graphene, silicon carbide, molybdenum disulfide or an organic semiconductor material.

Specifically, the material of the second active layer 42 is indium gallium zinc oxide (IGZO), indium oxide, zinc oxide, copper indium sulfide or indium gallium arsenide.

Specifically, the substrate 10 is a PI substrate, a PET substrate or a glass substrate.

Specifically, the material of the gate 20 is indium tin oxide (ITO) or one or more metal materials of molybdenum, aluminum, copper, titanium, and cadmium.

Specifically, the gate insulating layer 30 is a silicon nitride layer, a silicon oxide layer, a hafnium oxide layer, an aluminum oxide layer or an organic insulating layer;

Specifically, the material of the drain 51 and the source 52 is ITO or one or more metal materials of molybdenum, aluminum, copper, titanium, and cadmium.

Specifically, the passivation layer 60 is a silicon nitride layer, a silicon oxide layer, a hafnium oxide layer, an aluminum oxide layer or an organic insulating layer.

The TFT array substrate of the present invention adopts a dual-layer structure for the active layer 40. The first active layer 41 adopts a new semiconductor material of carbon nanotubes, graphene, silicon carbide, molybdenum disulfide or organic semiconductor materials. The second active layer 42 is disposed on the first active layer 41 to protect the first active layer 41 of the new semiconductor material from the wet etching and CVD process as an ESL and facilitates the active layer 40 of the TFT device to possess combined excellent properties of two semiconductor materials and lowering the production cost. Therefore, the TFT array substrate has an active layer 40 having higher mobility and less defects in thin film to improve reliability of the TFT device.

In summary, the invention provides a manufacturing method of TFT array substrate, wherein the active layer is provided as a dual-layer structure. The first active layer adopts a new semiconductor material of carbon nanotubes, graphene, silicon carbide, molybdenum disulfide or organic semiconductor materials. The second active layer is disposed on the first active layer to protect the first active layer of the new semiconductor material from the wet etching and CVD process as an ESL and facilitates the active layer of the TFT device to possess combined excellent properties of two semiconductor materials and lowering the production cost. Therefore, the TFT array substrate manufactured by the method of the present invention has an active layer having higher mobility and less defects in thin film to improve reliability of the TFT device.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A manufacturing method of thin film transistor (TFT) array substrate, comprising the steps of:
Step S1: providing a substrate, depositing a first metal film on the substrate, patterning the first metal film to form a gate, and forming a gate insulating layer covering the gate on the substrate;
Step S2: forming a first semiconductor film on the gate insulating layer, material of the first semiconductor film being an inorganic semiconductor material or an organic semiconductor material;
Step S3: forming a second semiconductor film on the first semiconductor film and patterning the second semiconductor film to obtain a second active layer corresponding to above of the gate; material of the second semiconductor film is metal oxide semiconductor material;
Step S4: depositing a second metal film on the first semiconductor film and the second active layer and patterning to form a drain and a source, the drain and the source respectively extending from both ends of the second active layer onto the first semiconductor film;
Step S5: using the drain, the source, and the second active layer as a shielding layer, performing etching processing on the first semiconductor film to obtain a first active layer, where the first active layer and the second active layer collectively forming an active layer.

2. The manufacturing method of TFT array substrate as claimed in claim 1, further comprising:
Step S6: forming a passivation layer covering the drain, the source, and the active layer on the gate insulating layer; forming a via corresponding to above of the drain on the passivation layer;
Step S7: depositing a third metal film on the passivation layer and patterning to form a pixel electrode, wherein the pixel electrode being connected to the drain through the via.

3. The manufacturing method of TFT array substrate as claimed in claim 1, wherein the material of the first semiconductor film is carbon nanotubes, graphene, silicon carbide, molybdenum disulfide or an organic semiconductor material;
the material of the second active layer is indium gallium zinc oxide (IGZO), indium oxide, zinc oxide, copper indium sulfide or indium gallium arsenide.

4. The manufacturing method of TFT array substrate as claimed in claim 1, wherein in step S5, the first semiconductor film is etched by plasma dry etching.

5. The manufacturing method of TFT array substrate as claimed in claim 1, wherein in step S3, the second semiconductor film is formed by magnetron sputtering or chemical vapor deposition (CVD)
in step S3, the specific process of patterning the second semiconductor film comprises a photoresist coating step, an exposure step, a development step, an etching step, and a photoresist removal step, all sequentially performed; wherein, the etching step on the second semiconductor film being performed by wet etching.

6. The manufacturing method of TFT array substrate as claimed in claim 1, wherein in step S2, the first semiconductor film is formed by coating.

7. The manufacturing method of TFT array substrate as claimed in claim 1, wherein the substrate provided in step S1 is a polyimide substrate, a polyethylene terephthalate substrate or a glass substrate;
the material of the gate formed in step S1 is indium tin oxide (ITO) or one or more metal materials of molybdenum, aluminum, copper, titanium, and cadmium;
the gate insulating layer formed in step S1 is a silicon nitride layer, a silicon oxide layer, a hafnium oxide layer, an aluminum oxide layer or an organic insulating layer;
the material of the drain and the source formed in step S4 is ITO or one or more metal materials of molybdenum, aluminum, copper, titanium, and cadmium;
the passivation layer formed in step S6 is a silicon nitride layer, a silicon oxide layer, a hafnium oxide layer, an aluminum oxide layer or an organic insulating layer.

8. A thin film transistor (TFT) array substrate, comprising: a substrate, a gate disposed on the substrate, a gate insulating layer disposed on the substrate and covering the gate, and an active layer disposed on the gate insulating layer and corresponding to above of the gate, and a drain and a source disposed on the active layer and respectively contacting two ends of the active layer;
the active layer comprising a first active layer disposed on the gate insulating layer, and a second active layer disposed on the first active layer covering a middle portion of the first active layer, the drain and the source extending from both ends of the second active layer onto the first active layer, respectively;
material of the first active layer being an inorganic semiconductor material or an organic semiconductor material;
material of the second active layer being a metal oxide semiconductor material.

9. The TFT array substrate as claimed in claim 8, wherein the material of the first active layer is carbon nanotubes, graphene, silicon carbide, molybdenum disulfide or an organic semiconductor material;
the material of the second active layer is indium gallium zinc oxide (IGZO), indium oxide, zinc oxide, copper indium sulfide or indium gallium arsenide.

10. The TFT array substrate as claimed in claim 8, further comprising: a passivation layer disposed on the gate insulating layer and covering the drain and the source, a via disposed on the passivation layer and corresponding to above of the drain, and a pixel electrode disposed on the passivation layer; the pixel electrode being connected to the drain through the via;
the substrate is a polyimide substrate, a polyethylene terephthalate substrate or a glass substrate;
the material of the gate is indium tin oxide (ITO) or one or more metal materials of molybdenum, aluminum, copper, titanium, and cadmium;
the gate insulating layer is a silicon nitride layer, a silicon oxide layer, a hafnium oxide layer, an aluminum oxide layer or an organic insulating layer;
the material of the drain and the source is ITO or one or more metal materials of molybdenum, aluminum, copper, titanium, and cadmium;
the passivation layer is a silicon nitride layer, a silicon oxide layer, a hafnium oxide layer, an aluminum oxide layer or an organic insulating layer.
